(19) United States
(12) Patent Application Publication
(10) Pub. No.: US 2002/0061472 A1
(43) Pub. Date: May 23, 2002

(54) Three-dimensional lithography by multiple two-dimensional pattern projection

(75) Inventors: Gregory D. Cooper, Alexandria, VA (US); Erin F. Fleet, Alexandria, VA (US)

Correspondence Address: NIXON & VANDERHYE P.C., 8th Floor, 1100 Glebe Road, Arlington, VA, 22201, US

(73) Assignee: Pixelligent Technologies LLC.

(21) Appl. No.: 09/988,216

(22) Filed: Nov. 19, 2001

Related U.S. Application Data
(60) Provisional application No. 60/249,261, filed on Nov. 17, 2000.

(51) Int. Cl. G03F 7/20

(52) U.S. Cl. 430/322; 430/396

(57) ABSTRACT

Two programmable masks are used for the exposure of three-dimensional patterns in a photosensitive material. This exposure technique takes advantages of symmetries and repeating structures in the exposure pattern to reduce the exposure time, while maintaining the flexibility to produce complicated three-dimensional shapes.

### CROSS-REFERENCES TO RELATED APPLICATIONS

This application claims the benefit of Provisional Application No. 60/249,261, filed Nov. 17, 2000, the entire content of which is hereby incorporated by reference in this application.

### STATEMENT REGARDING FEDERALLY SPONSORED RESEARCH OR DEVELOPMENT

Not applicable.

### FIELD OF INVENTION

This invention relates to the fabrication of three-dimensional objects, and more particularly to systems, methods, and techniques for creating three-dimensional objects lithographically. Still more particularly, the present invention relates to systems, methods, and techniques using multiple programmable masks to lithographically create three-dimensional objects.

### BACKGROUND AND SUMMARY OF THE INVENTION

Lithography is a well-known technique used to create two-dimensional structures. It involves transferring a pattern from one surface to another. For example, a common type of lithography, known as photolithography, is the driving technology in manufacturing Integrated Circuits (ICs). In photolithography, a permanent mask consists of an opaque material that is selectively located on a transparent substance in the desired pattern. Light is incident on the mask and a shadow from the patterned opaque regions is cast onto a substrate coated with a light sensitive material known as a photo-resist. The photo-resist changes its chemical properties when light impinges upon it. The resist is then developed to remove the exposed (or unexposed) areas of the resist. In this process, the pattern from the mask is transferred to the photo-resist. There is usually further processing by developing and other processing to create resistant structures. Lithography now can create features that are 40 nanometers in size with 248 nm light. In lithography for creating two-dimensional structures, the permanent mask can be replaced with a programmable mask (see Cooper and Mohring, Ser. No. 09/066,979, Transferring A Programmable Pattern By Photon Lithography). A programmable mask is a mask that can be easily reconfigured to produce many different patterns. A programmable mask typically consists of a two-dimensional array of pixels. For example, in photolithography, each pixel can modulate the incident light in a small area on the photo-resist. Conceptually, a programmable mask substantially increases the flexibility of a lithography system while maintaining the high throughput. For instance, a single programmable mask can be used to make any IC. Without a programmable mask each IC requires ˜20 permanent masks to be specially made and those masks can only be used to make that specific IC.

Lithography has also been adapted to make three-dimensional objects. In one scheme (see FIG. 1) a three-dimensional container of a photosensitive material, analogous to the photo-resist in two-dimensional photolithography, is exposed using two independently controllable light beams. FIG. 1 shows the use of two scanned laser beams to create a three-dimensional object in a container of photosensitive material. The photosensitive material is only exposed at the intersection of the two laser beams. The laser beams can have different or the same wavelengths. The photosensitive material only becomes exposed (changes its chemical properties via polymerization, for example) at the intersection of the two beams. The intersection of the two beams is then scanned over the three-dimensional container of the photosensitive material in accordance with the desired three-dimensional pattern. The chemical properties of the photosensitive material have been changed in some places and not in others. The unexposed material can then be dissolved, melted away, or otherwise removed. This process leaves the desired three-dimensional pattern in the exposed photosensitive material.

There are several mechanisms by which the crossing of two beams would cause significant exposure of the photosensitive material, while one beam does not. One possible mechanism is to have the two radiation beams have different wavelengths. Exposure of the resist would then require the absorption of both wavelengths within a short period of time.

Another known mechanism is to have both beams be the same wavelength but have the exposure rate be a non-linear function of the light intensity. In this case, the intensity from a single beam would cause the photosensitive material to be exposed slowly. The intensity from the two beams would cause the photosensitive material to be exposed quickly. Ordinarily doubling the intensity would only double the exposure rate. For a material where the exposure rate is a non-linear function of the light intensity, doubling the light intensity more than doubles the exposure rate.

Besides those given above, there are other possible schemes for exposing a photosensitive material to create a three-dimensional object. For example, three beams of either the same or different wavelengths could be required to expose the photosensitive material. Alternatively, a third beam could be used to prevent exposure at the intersection of two beams.

There are several problems with such techniques of three-dimensional lithography using intersecting beams. The most obvious and detrimental is speed; every point in an object is exposed sequentially, which makes the process very slow. Furthermore, a vast amount of the incident radiation is not being used to expose the intended region. It is either wasted, or, worse still, it is causing slight but possibly troublesome changes in the photosensitive material outside of the desired region of exposure.

Another technology for creating three-dimensional objects is known as stereolithography. In stereolithography, a thin layer of a liquid polymer is patterned by selectively exposing the polymer to a light source. The exposure to the light source hardens or cures the liquid polymer. Three-dimensional objects are built one layer at a time. Usually a laser source is scanned across the substrate as the exposure method.

This method suffers similar problems with the multiple beam three-dimensional lithography described above. The process is essentially serial and, as a result, slow. To speed up the process, often the entire part is not exposed during the stereolithographic process. Instead, the surfaces and some supporting structures are exposed. This leaves a defined part, but with many pockets of unexposed materials throughout the part. This “mesh” is then placed in some sort of flood curing device, where the remaining unexposed areas are exposed. This process, however, introduces other difficulties. For example, it is well known that while exposing the pockets, mechanical deformations can occur between the pockets and the previously exposed regions.

Instead of using a scanning beam, there have been suggestions to use a programmable mask to expose an entire layer at once during stereolithography. This has the advantage of speeding up the stereolithography process because the exposure process becomes parallel in two dimensions. However, the process is still serial in the third dimension.

The present invention overcomes many of the disadvantages of prior three-dimensional image creation processes. It also provides further improvements that can significantly enhance the ability to make more complicated three-dimensional structures at lower cost.

One aspect provides a new technique where two programmable masks are used for the exposure of three-dimensional patterns in a photosensitive material. This exposure technique takes advantages of symmetries and repeating structures in the exposure pattern to reduce the exposure time, while maintaining the flexibility to produce complicated three-dimensional shapes. We have used the term voxography to refer to using multiple programmable masks in a three-dimensional lithography system. The term voxography comes from combining lithography with voxel. A voxel is volume pixel or three-dimensional region analogous to a pixel in a two-dimensional system.

To understand voxography, consider the process outlined in FIG. 2-FIG. 3. FIG. 2 shows an example conceptual flowchart of 3D lithography. A user sends his part design to the Exposure Process Computer. This Computer calculates the exposure process, and sends it to the Exposure Controller. The Controller performs the exposure process, yielding a finished part. FIG. 3 shows an exemplary flowchart for 3D lithography in more detail and explicitly states illustrative steps of FIG. 2, including a step for post-exposure processing that includes removing the unexposed material and cleaning up the part. The process starts with a part design, computer generated or otherwise. The design is analyzed by, for example, an exposure process computer, to determine an exposure process to produce the part. An exposure controller uses the exposure process to control the elements of the voxography apparatus to expose the part design. If necessary, final part clean-up or other steps can occur in post-exposure processing. The final result is a part embodying the original design.

FIG. 4 shows the elements of an exemplary illustrative embodiment of a voxography apparatus, including the exposure process computer, the exposure controller, and the programmable masks. The exposure controller is performing the first step in the exposure process for making an arbitrary part design. Three pixels in each mask are turned “on”, exposing three voxels of the photosensitive material. Any post-exposure processing is not represented in FIG. 4.

Using the technique described in the current invention a rectangular solid could be exposed in a single exposure. One programmable mask would project an image of a rectangle and a second perpendicular (or orthogonal) programmable mask would project an image of a second rectangle. In stereolithography this would be accomplished by exposing a series of stacked rectangles, requiring many exposures instead of one.

Using multiple programmable masks is a way of making the exposure process more parallel, while retaining the ability to create complicated three-dimensional structures. Multiple layers can be exposed at one time if there are symmetries or repeating structures in the exposure pattern. Almost all parts have some symmetries or regularities that will allow decreases in exposure time. Many parts will also have asymmetrical portions, which can still be efficiently produced due to the flexibility offered by the programmable masks.

Additionally, the exposure need not be in sequential horizontal layers as has been described for stereolithography. Instead, the exposure can consist of a sequence of layers chosen to exploit symmetries of the object to be exposed. For example, the exposure could occur in concentric, cylindrical layers to take advantage of a rotational symmetry in the object.

In addition to speeding up the exposure process there are several other advantages to using voxography. It reduces the total radiation incident on the photosensitive material. With voxography, a much larger percentage of the incident light is used to expose the photosensitive material. This means that the photosensitive material can be more tolerant of the light inducing undesired chemical changes in the photosensitive material at points outside of the desired exposure pattern. Also, less incident light means that the system will use less energy, increasing efficiency and decreasing the cost of operation.

Another advantage of using a programmable mask in three-dimensional lithography is the possibility of using feedback to adjust the exposure pattern. The optical, chemical, or mechanical properties of the photosensitive material can change as it is exposed. With a feedback system, the changes in the system are monitored (preferably using the optical characteristics of the photosensitive material) and the exposure pattern is adjusted accordingly. Programmable masks are useful in systems involving feedback because the programmable mask can be easily changed to optimize the desired exposure pattern. (The changes in the optical, chemical, or mechanical properties of the photosensitive material would need to be taken into account even if there is no feedback.)

In accordance with further aspects, more than two programmable masks are used for exposing a three-dimensional pattern in a photosensitive material. Using more programmable masks can further decrease the time required to expose a three-dimensional pattern. In the case where the programmable masks do not project a fully dense pattern (meaning that the pixels in the image do not occupy 100% of the image area), two programmable masks that are located opposite of each other are aligned so that one of the masks exposes areas not exposed by the other. In the case where the object to be imaged has non-perpendicular symmetries, multiple masks can expose the photosensitive material in non-perpendicular directions.

FIG. 5 shows an example apparatus for exposure with non-perpendicular masks. In this case the non-perpendicular masks allow us to take advantage of the symmetries in the object to be exposed. This drawing shows an illustrative example of this where the part has two structures joined at a 60° angle. By having two programmable masks projecting along directions separated by 60°, along with a third mask perpendicular to the other two, the part can be made in one exposure.

In accordance with further illustrative aspects, one or more of the programmable masks can be replaced with a permanent or re-writable mask. This system would be less flexible than one with all programmable masks. However, certain parts may not require the flexibility or high performance of a programmable mask. Also, certain parts may not require high resolution in all directions and could thus use a re-writable mask in that direction. Fixed masks, such as those found in conventional semiconducting manufacturing facilities, have the disadvantage that they are only useful for one part design, and must be replaced for every new part design, or even for every sub-part of the full part. The re-writable masks require extra equipment and materials to perform each wipe and re-write of a pattern, which also makes them much slower than the programmable masks.

In accordance with further illustrative aspects, one or more of the programmable masks can be replaced with a selective amplifier or programmable layer (see Cooper and Mohring, Ser. No. 09/066,979, Transferring A Programmable Pattern By Photon Lithography). A selective amplifier is similar to a programmable mask, except that it creates a pattern by increasing the intensity of light (amplifying) in some places and not in others where a programmable mask creates a pattern by decreasing the intensity of light in some places and not in others. A programmable layer is a combination of a selective amplifier with a programmable mask. Ordinarily in a programmable layer the corresponding pixels for the selective amplifier (amplifying or not-amplifying) and programmable mask (transparent or opaque) would be in the same state (amplifying-transparent or not-amplifying-opaque). For this application that need not be the case. The programmable layer could be in one of three configurations amplifying-transparent, not-amplifying-transparent, or not-amplifyin-gopaque (the fourth possibility, amplifying-opaque, is the same as not-amplifying-opaque). This would produce a light pattern with three intensities—amplified, not-amplified, and off.

There are several advantages to including selective amplification. For example, it can be used to increase the intensity of light incident on the photosensitive material. This can help increase the speed of the exposure process.

Another advantage of including a programmable layer (or other device that can modulate the intensity and not just switch between on and off) is that it can be used to change the number of intersecting beams needed to produce exposure. For example, consider a photosensitive working material which requires a certain intensity of light at a single wavelength to expose (as opposed to one that requires incident light of multiple wavelengths). Without selective amplifiers, every “on” pixel yields an intensity I. In a three mask system, exposure of a voxel requires light of intensity 31, or all 3 beams. With selective amplifiers, each “on” pixel might be configured to produce either I or 21 intensity. Thus, only 2 beams, one of intensity I and one of intensity 21 will expose the material. However, three beams could also be required, with each set to intensity I. Essentially, including a programmable layer would allow the exposure to dynamically switch between requiring the intersection of two or three beams. This could allow more complicated patterns to be created in each shot and could further reduce the total exposure time (or number of exposures) required to expose a three-dimensional pattern.

In another illustrative embodiment, multiple parts can be made by projecting multiple copies of each part in an N×N array from each perpendicular direction. FIG. 6 shows an illustrative multiple pattern projection used to make multiple parts. In this scheme three intersecting beams are required to expose the photosensitive material. Each projected light pattern is used to make two copies of the desired object. This exposure scheme is analogous to the exposure scheme shown in FIG. 11. For example, in FIG. 6, there is an N×N array of masks for each perpendicular direction. Each mask is producing one pattern. Alternatively, one mask in each direction could be producing an N×N array of patterns. There could also be an array of masks in each direction, with each mask producing an array of patterns. In other words, the multiple copies of each pattern can come from the same mask or from multiple masks. With this exposure scheme N³ parts are created where only 3 N² patterns are required. When N=1 (see FIG. 11), 1 part is made with 3 patterns. When N=2 (see FIG. 6), 8 parts are made with 12 patterns. If N=5, 125 parts would be made with only 75 patterns. This provides an economical way to produce multiple copies of the same part.

### BRIEF DESCRIPTION OF THE DRAWINGS

These and other features and advantages provided by the invention will be better and more completely understood by referring to the following detailed description of presently preferred embodiments in conjunction with the drawings. The file of this patent contains at least one drawing executed in color. Copies of this patent with color drawing(s) will be provided by the Patent and Trademark Office upon request and payment of the necessary fee. The drawings are briefly described as follows:

FIG. 1 shows using two crossed beams to expose a photosensitive material in order to create a three-dimensional object;

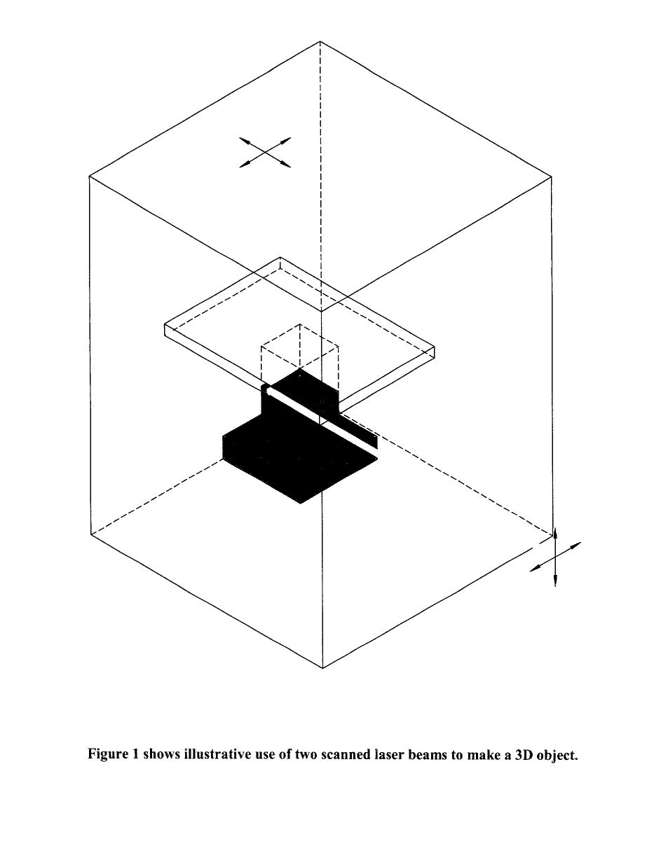

FIG. 2-FIG. 3 show flowcharts for an exemplary illustrative voxography process.

FIG. 2 is a conceptual version of the process. A user sends a part design to the Exposure Process Computer. This computer determines an efficient exposure process for producing the part. This process is sent to the Exposure Controller, which controls the programmable masks and other parts of the voxography machine. After exposure, some post-exposure processing may be used. This step may include activities such as removing the unexposed material from the part and final part clean-up. The final product is the designed part;

FIG. 3 shows a block flowchart outlining the above process;

FIG. 4 shows a simplified example of a three-dimensional lithography technique in accordance with a preferred embodiment of the present invention using multiple programmable structures;

FIG. 5 shows a simplified example of a three-dimensional lithography technique in accordance with an alternative embodiment of the present invention using multiple non-perpendicular programmable structures;

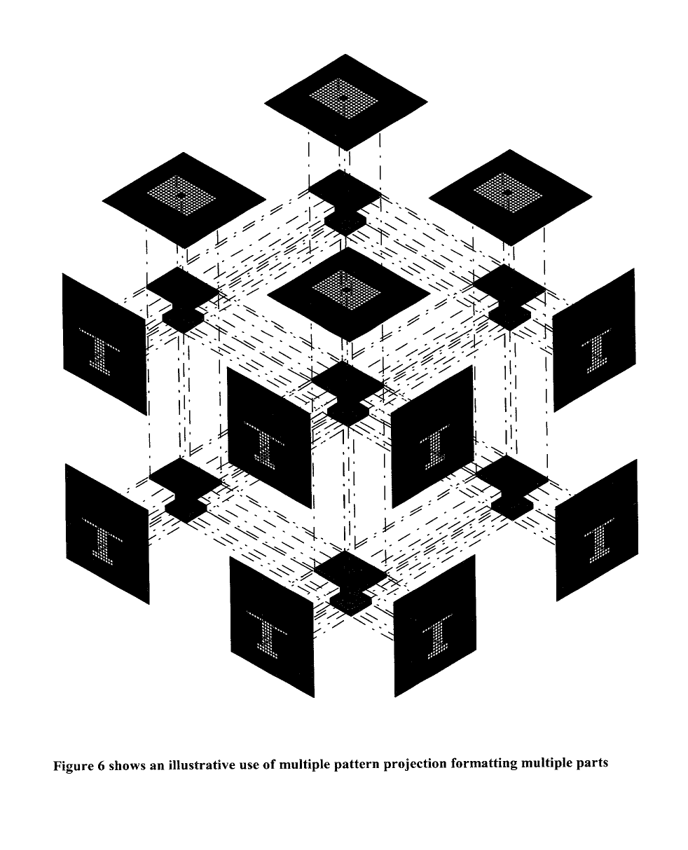

FIG. 6 shows a simplified example of a three-dimensional lithography technique for making multiple copies of the same part using multiple pattern projections;

FIG. 7-FIG. 10 show two example operations of an example preferred embodiment to expose a simple table-like part using two programmable structures.

FIG. 7-FIG. 9 show each step of a three-step exposure process.

FIG. 10 shows a one step exposure process. The difference between the two exposure processes is that the part has been rotated by 90°;

FIG. 11 shows a one-step exposure process for producing a simple table-like structure using a three mask system. This structure is identical to that of FIG. 7-FIG. 9 except for a central hole through the table. Note that it would take multiple exposure steps for the two-mask system to make this same part;

FIG. 12 shows a flow chart for one possible procedure for determining an exposure process; and

FIG. 13 shows an exemplary procedure of the FIG. 12 flowchart embodied in a pseudo-code algorithm.

### DETAILED DESCRIPTION OF EXAMPLE EMBODIMENTS

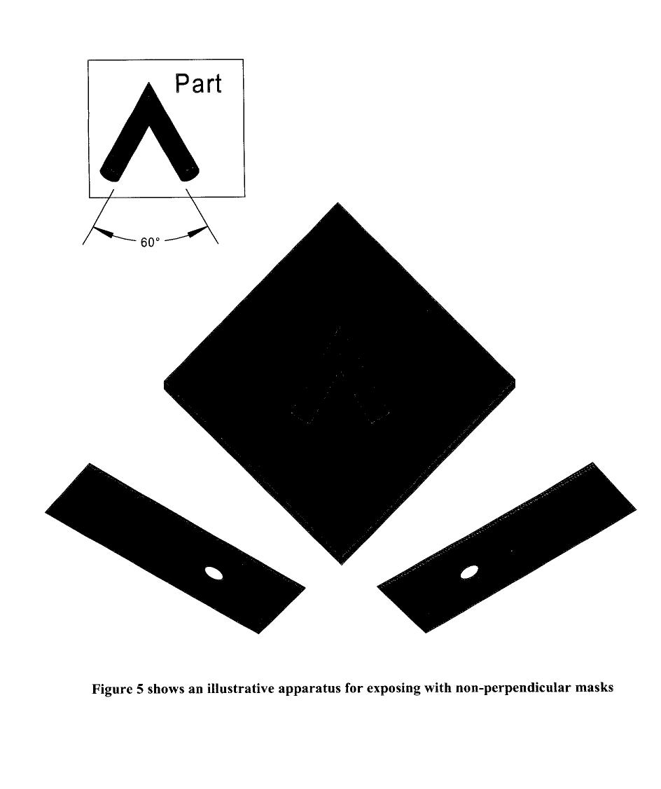

An example preferred embodiment comprises two two-dimensional programmable masks, light sources for each, a container of photosensitive material, a computer employing an algorithm to determine the exposure scheme, and an exposure controller to control the exposure process. FIG. 4 discussed above shows these four components incorporated into an example setup for performing voxography.

The two programmable masks are arranged such that the normal of the plane of each mask is perpendicular to that of the other mask, thus exposing perpendicular directions throughout the material. Each mask is placed in the optical path between its light source and the container of photosensitive material. The masks are mounted such that they can be moved in the plane of the mask.

The light sources can be two independent light sources of same or different wavelengths. The light may be coherent or incoherent. It can also be from the same source, but split to illuminate each of the two masks. Note that even if the same source is used for illuminating all the masks, it is possible to still have each mask illuminated by different wavelengths of radiation by appropriate apparatus before or after each mask (not shown).

Another preferred embodiment comprises three two-dimensional programmable masks, light sources for illuminating each, a container of photosensitive material, a computer employing an algorithm to determine the exposure scheme, and an exposure controller to control the exposure process.

The three programmable masks are arranged such that the normal of the plane of each mask is perpendicular to the normals of the planes of the other masks, thus exposing perpendicular directions throughout the material. Each mask is placed in the optical path between its light source and the container of photosensitive material.

The light sources can be multiple independent light sources of same or different wavelengths. The light may be coherent or incoherent. It can also be from the same source, but split to illuminate each of the masks. Note that even if the same source is used for illuminating all the masks, it is possible to still have each mask illuminated by different wavelengths of radiation by appropriate apparatus before or after each mask (not shown).

In another alternative embodiment, the invention consists of 4, 5 or 6 programmable masks, light sources for illuminating each, a container of photosensitive material, a computer employing an algorithm to determine the exposure scheme, and an exposure controller to control the exposure process.

When 4 masks are used, two of the programmable masks are arranged such that the normal of the plane of each mask is perpendicular to the normal of the plane of the other mask, thus exposing two perpendicular directions throughout the material. Each of the other two masks is across the container of photosensitive material directly opposite each of said perpendicular masks. Alternatively, three of the programmable masks are arranged such that the normal of the plane of each mask is perpendicular to the normal of the plane of the other two masks. The fourth mask is across the container of photosensitive material directly opposite one of said perpendicular masks. In the case where the programmable masks are not fully dense (for instance where the pixels occupy only one fourth of the area of the mask), the oppositely located programmable masks can be placed such that the pixels from one mask expose the areas not exposed by the other mask. Each mask is placed in the optical path between its light source and the container of photosensitive material. In the case of 5 or 6 masks, 3 of the masks are arranged such that the normal of the plane of each mask is perpendicular to the normals of the planes of the other masks. Each of the remaining masks is placed directly opposite the container from one of said perpendicular masks. The masks are mounted such that they can be moved in the plane of the mask.

The light sources can be multiple independent light sources of same or different wavelengths. The light may be coherent or incoherent. It can also be from the same source, but split to illuminate each of the masks. Note that even if the same source is used for illuminating all the masks, it is possible to still have each mask illuminated by different wavelengths of radiation by appropriate apparatus before or after each mask (not shown).

Another alternative illustrative embodiment comprises a plurality of programmable masks, a plurality of light sources, a container of photosensitive material, a computer to determine the exposure scheme, and an exposure controller to control the exposure process. The plurality of programmable masks are arranged to expose different directions throughout the photosensitive material. Alternatively, some of the plurality can expose different directions, while others can be across said container of photosensitive material directly opposite said masks.

The light sources can be independent light sources of same or different wavelengths. The light may be coherent or incoherent. It can also be from the same source, but split to illuminate each of the masks. Note that even if the same source is used for illuminating all the masks, it is possible to still have each mask illuminated by different wavelengths of radiation by appropriate apparatus before or after each mask (not shown).

Another alternative illustrative embodiment comprises one of the above embodiments, but with one or more programmable masks replaced with an array of selective amplifiers or a combination of a programmable mask and an array of selective amplifiers.

In another alternative embodiment, one or more programmable masks is replaced with a permanent mask, a series of permanent masks, or a re-writable mask such as the electrostatically bound toner masks used in some photocopier machines.

In another alternative embodiment, one or more of the programmable masks is replaced with a programmable array, a fixed array, or a series of fixed arrays of light sources (such as LEDs).

In another alternative embodiment, a fixed container of photosensitive material is replaced with a rotatable or otherwise moveable container.

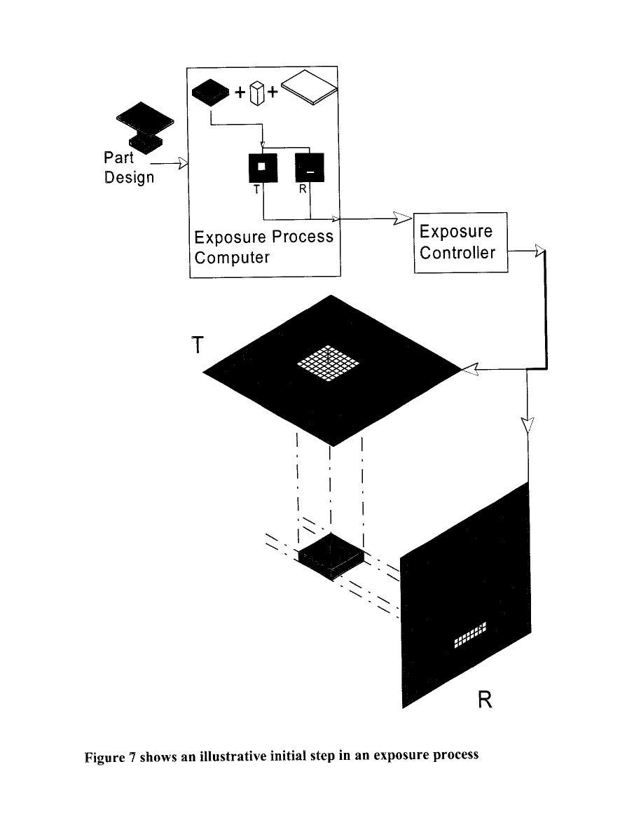

In another alternative embodiment, multiple parts are made by projecting multiple copies of each part in an N×N array from multiple directions (see FIG. 6, where N=2). The multiple copies of each pattern can be projected in each direction by one mask or multiple masks.

### EXAMPLE OPERATION OF PREFERRED EMBODIMENTS

In voxography, intersecting projections of two-dimensional patterns of light expose photosensitive materials for rapid three-dimensional object creation. In the simplest embodiment, a container holds photosensitive material that changes properties under an appropriate exposure or intensity of radiation. One or more sources of light illuminate two perpendicular programmable masks. The illumination is such that exposure of a voxel from only one mask does not cause substantial change in said medium, while exposure from both masks does.

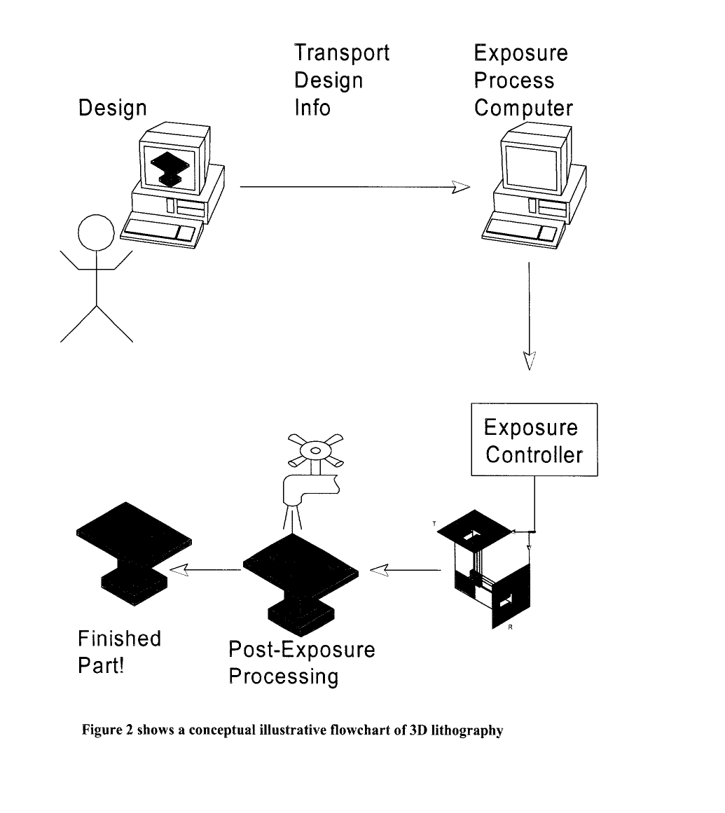

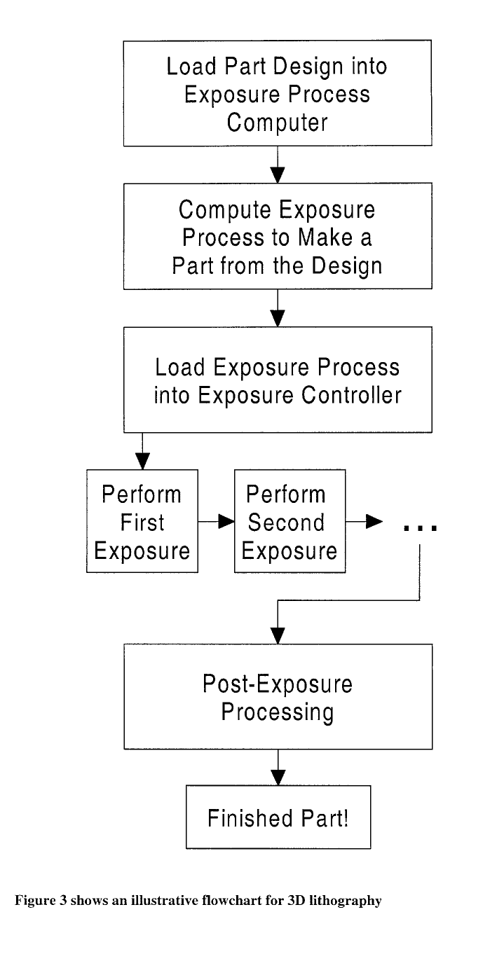

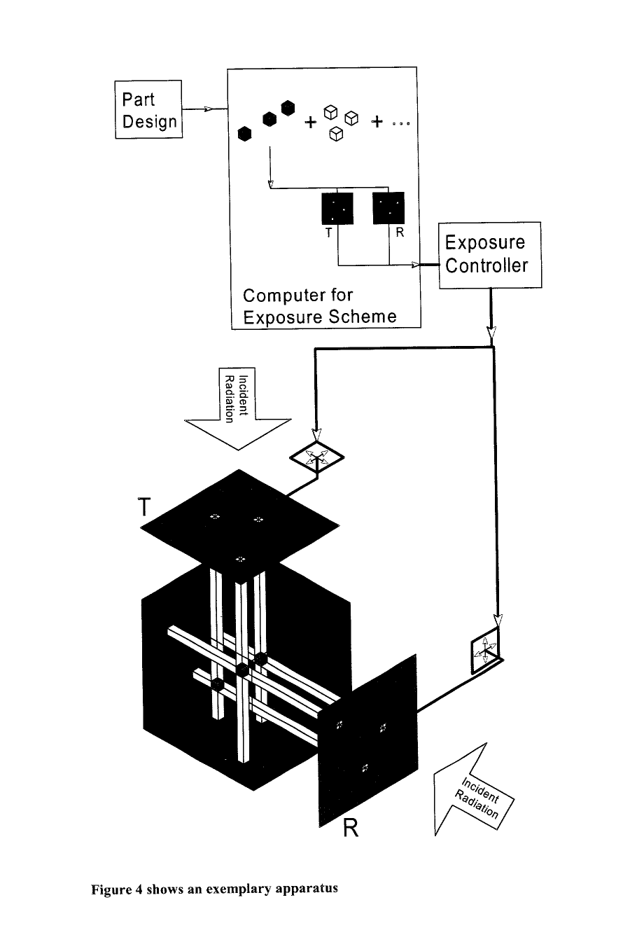

FIG. 2-FIG. 3 outline a typical voxography process. First, the design of the object or objects to be created is analyzed, by a computer or otherwise. The analysis determines an exposure scheme for producing said object or objects. (The exposure scheme can be optimized for minimal exposure time, minimal dimensional tolerances, or these factors in combination with others in a predetermined trade-off (such as tolerance for speed)).

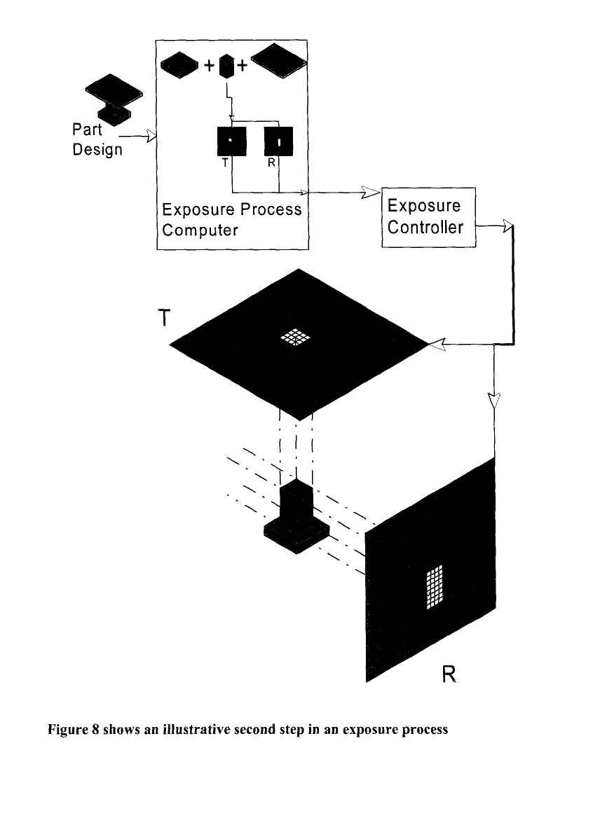

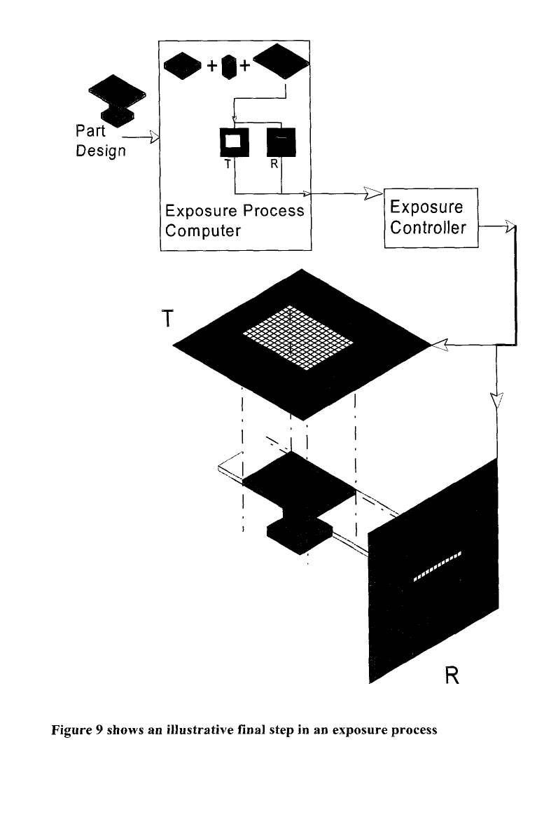

FIG. 7 shows an example overall apparatus. The first step in the exposure of a “table”. A computer file with the part design is loaded into the Exposure Process Computer. The Exposure Process Computer determines how many exposures are required to create the object and which shutters should be opened in each exposure step. This information is downloaded to the Exposure Controller. The Exposure Controller directly controls the programmable masks. In this step the entire base is exposed in one shot. The top mask opens a square (8 pixels by 8 pixels) and the side mask opens a rectangle (8 pixels by 2 pixels. The intersection of the two beams produces a rectangular solid (8 pixels by 8 pixels by 2 pixels).

FIG. 8 shows an exemplary second step in the exposure of a table. A computer file with the part design is loaded into the Exposure Process Computer. The Exposure Process Computer determines how many exposures are required to create the object and which shutters should be opened in each exposure step. This information is downloaded to the Exposure Controller. The Exposure Controller directly controls the programmable masks. In this step the entire support is exposed in one shot. The top mask opens a square (4 pixels by 4 pixels) and the side mask opens a rectangle (4 pixels by 8 pixels. The intersection of the two beams produces a rectangular solid (4 pixels by 4 pixels by 8 pixels).

FIG. 9 shows an exemplary third and final step in the exposure of a table. A computer file with the part design is loaded into the Exposure Process Computer. The Exposure Process Computer determines how many exposures are required to create the object and which shutters should be opened in each exposure step. This information is downloaded to the Exposure Controller. The Exposure Controller directly controls the programmable masks. In this step the entire top is exposed in one shot. The top mask opens a square (12 pixels by 16 pixels) and the side mask opens a rectangle (12 pixels by 1 pixel. The intersection of the two beams produces a rectangular solid (12 pixels by 16 pixels by 1 pixels).

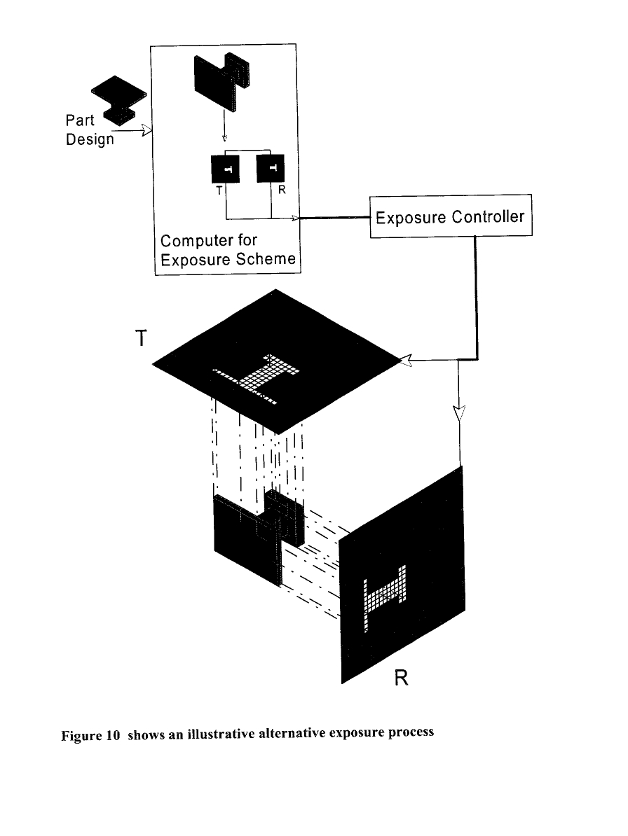

The exposure scheme depends on many details of the object. For example, the simple table, shown in FIG. 7-FIG. 9, consists of the following structures: a base, support, and top. This object requires many exposures in a stereolithography machine (with or without a programmable mask). In a voxography machine with two programmable masks, an exposure process can be found which makes the table in only 3 exposures, one exposure for each structure, greatly reducing manufacturing time for the table. Furthermore, if the table can be rotated (see FIG. 10), it can be made in only one exposure.

FIG. 10 shows an illustrative alternative exposure process for exposing the simple table. With one exposure, this exposure process creates the same part that took three exposures in the process shown in FIG. 7-FIG. 9. Note that all that was needed was a simple rotation of the table.

A controller, preferably a computer connected to the programmable masks and the radiation source(s), uses the exposure process to create the part. The controller controls the individual pixels on the programmable masks. With suitable choice of pixel size and/or optics between the mask and the container, each pixel can produce a column of radiation. This column passes through the container. An intersection of these columns from both masks exposes the material, changing its physical properties.

An advantage of voxography is that very complicated three-dimensional objects can be created while taking advantage of symmetries and regularities in the object to reduce the exposure time. Previous inventions have described the creation of three-dimensional objects where the exposure is parallel in two dimensions and serial in the third. One of the advantages of this new invention is a way to make the exposure in the third dimension at least partially parallel while maintaining parallel exposure in the other two dimensions. There may be three-dimensional objects that cannot be produced any faster than a three-dimensional lithography system with a single programmable mask. However, nearly all manufactured objects have symmetries or repeated patterns where the exposure scheme described in this patent will reduce the exposure time.

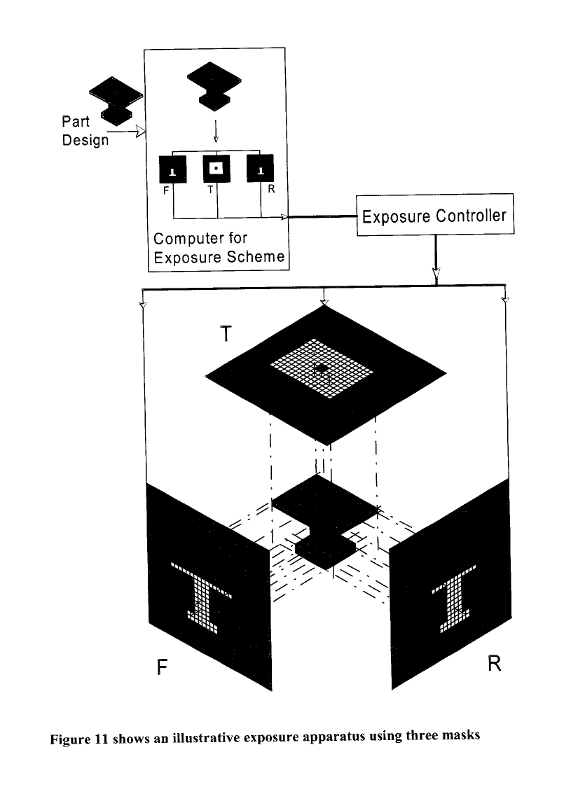

In a second embodiment, the intersection of three beams is required in order to expose the photosensitive material. FIG. 11 shows the exposure of the same table that was exposed in FIG. 7-FIG. 10, except a hole has been added through the middle of the table. Adding the third mask allows this part to be exposed all at once, where with only two masks more than one exposure would be required.

There are other possible exposure schemes using three programmable masks. FIG. 11 shows the case where light from all three masks, call them A, B, and C, is required for exposure. We call this an A+B+C exposure method. However, the intensity of light transmitted from a mask could be set such that exposure only requires light from two of the three masks—A+B, A+C, or B+C. In exposure requiring two different wavelengths, one mask, A, could provide one wavelength, while B and C provide the other wavelength. This would mean that A+B or A+C exposes the part, but B+C does not. In another alternative, the intersection of two beams could cause exposure, while adding the third beam prevents the other two beams from exposing the photosensitive material (A+B exposes and A+B+C does not expose).

Illustrative Algorithms

The illustrative embodiment benefits from an efficient method (an algorithm, for example) for determining the exposure scheme. The method could theoretically take many different factors into account. These factors would include the shape of the object, the location and orientation of the masks, and the number of beams required to expose the photosensitive material. The method could also take into account factors such as the changing optical, chemical, and mechanical properties of the photosensitive material as it is exposed.

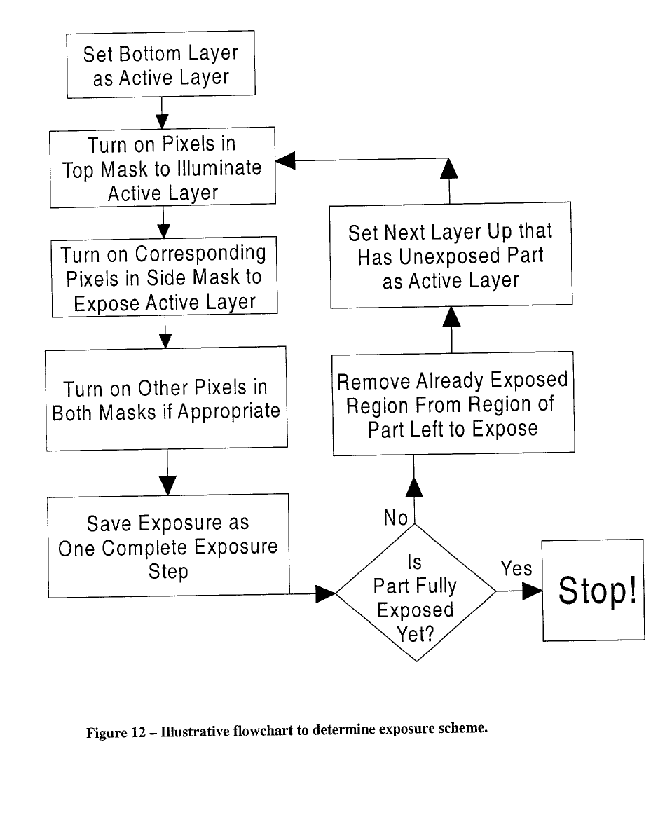

An example of a procedure for determining an exposure scheme is shown as an illustrative flow chart in FIG. 12. The procedure assumes that two intersecting beams are required to expose the photosensitive material and that the masks are perpendicular to each other. First, the bottom layer of the part design is set to be the active layer. Pixels in the top and side mask that correspond to the active layer are turned on. In the exemplary procedure for determining an exposure scheme, “turning on” a pixel means that the pixel should be turned on when the part is being exposed. Typically, no pixels are actually turned on during this step of the voxography process.

Then, the procedure turns on other pixels in the two masks “if appropriate”. “If appropriate” means that these pixels expose voxels which are in the part design without exposing voxels outside of the part design. Once all of the pixels that can be turned on are marked, the state (either on or off) of all the pixels in the masks is stored (computer file or otherwise) as an exposure. Then, the part design is stripped of all voxels exposed by this exposure. If there is any part design remaining to be exposed, the next layer that has unexposed part design and is above the current active layer is set as the new active layer. The process is repeated until there is no part design left, which means the part is fully exposed by the set of exposures stored during this procedure.

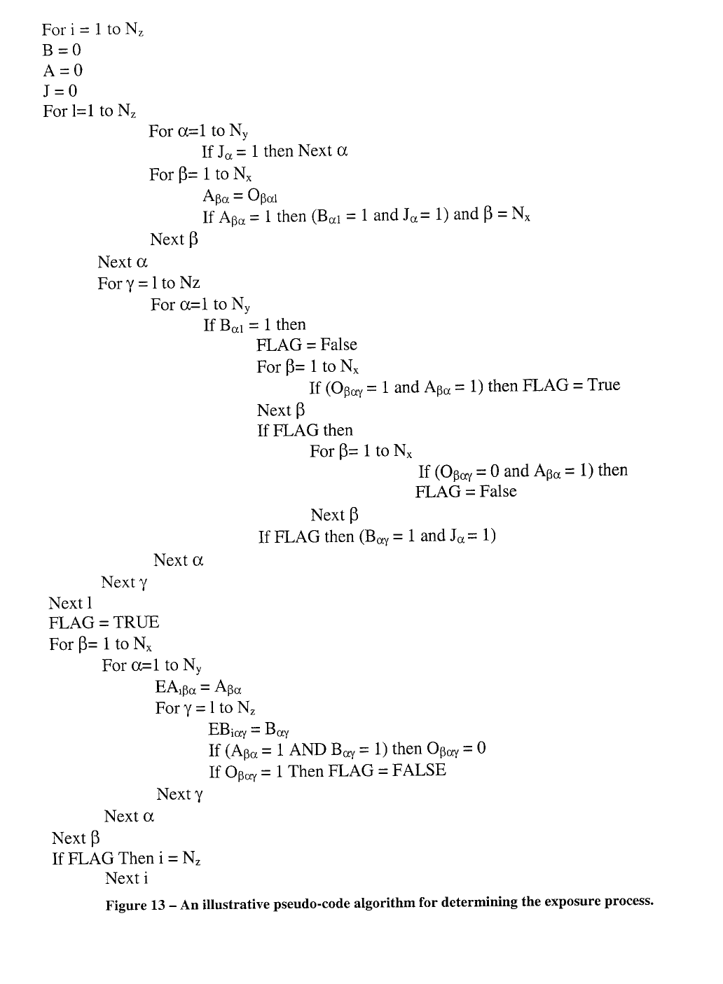

FIG. 13 shows an illustrative pseudo-code algorithm implementing the above procedure. The algorithm works on a three-dimensional matrix (O in the pseudo-code) that represents the object as an array of voxels that need to be exposed. The algorithm starts at the “bottom” of the object by turning on only the pixels required to expose the bottom layer. Initially, on the top mask (A in the pseudo-code) a two-dimensional array of pixels are opened and on the side mask (B in the pseudo-code) some pixels in the row corresponding to the bottom of the object are turned on. The algorithm then checks to see if additional pixels in the side mask can be turned on (i.e. it makes sure that no unwanted voxels are exposed) and if there is any benefit (i.e. exposing some voxels that need to be exposed) to turning on those additional pixels. The algorithm then checks to see if there are additional pixels on the top mask that could be turned on and if there is any benefit to turning on those pixels. The pixels on the side mask corresponding to the newly opened pixels on the top mask are then turned on. The algorithm then re-checks to see if additional pixels in the side mask can be turned on and if there is any benefit (i.e. exposing some voxels that need to be exposed) to turning on those additional pixels. This process is repeated until the maximum number of pixels are turned on. This represents one exposure. This exposure is saved in the matrices EA and EB, the final exposure matrices for the top and side masks respectively. The algorithm then calculates which voxels were exposed and subtracts those from the three-dimensional matrix representing the object. If the object has been completely exposed then the algorithm stops and if not then the algorithm calculates the next exposure. This process is repeated until the object is completely exposed. The final output from the pseudo-code is the exposure matrices EA and EB. The exposure controller could then use these matrices to expose the actual part. (Another way to think of this algorithm is that it breaks a three-dimensional object down into a series of simultaneous two-dimensional projections.)

This algorithm, or any other exposure process algorithm, could be repeated for many different orientations of the object. The results from the different orientations could be compared to determine which orientation of the object produces the most efficient exposure. One possible criterion for determining the most efficient exposure would be the fewest number of exposures required to expose the entire object.

There are other possible criteria. One other possible example where the orientation would be important is if the minimum voxel size is large compared to the feature size of the object. Some orientations could more accurately reproduce the desired object. FIG. 7-FIG. 11 show how the orientation of the object would affect the number of exposures. In one orientation the entire object could be exposed at once. In another orientation three exposures are required. The exposure pattern shown in FIG. 7-FIG. 9 are not the exposures that would result from the algorithm described here. Both exposure schemes preferably use three exposures.

One technique that the algorithm could use to find the fewest exposures or other desirable exposure properties is to look at the symmetries and other regularities of the object to be exposed. For example, a part design with angular symmetry about a central axis, such as a cylinder, could be analyzed in a different manner. Instead of working layer by layer as above, the analysis could start at the central axis of the part and work outwards radially.

Example applications include rapid prototyping, microfabrication, nanofabrication, 3D imaging, or the manufacturing of any kind of structure of any size, including for example high precision machine parts.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the scope of the claims.

What is claimed is:

1. A method of creating structures comprising:
(a) directing multiple two-dimensional patterns of irradiating energy toward a volume of photosensitive material so that said multiple patterns intersect; and
(b) subjecting said irradiated photosensitive material to a further process that creates a persistent 3D structure based on intersections between said multiple irradiating patterns.

2. The method of claim 1 wherein said directing step includes directing said irradiating energy toward said volume through a programmable mask.

3. The method of claim 1 wherein said directing step includes projecting multiple intersections of said two-dimensional patterns toward said photosensitive material.

4. The method of claim 1 wherein said photosensitive material comprises a photoresist that responds to the intersection between said multiple patterns.

5. The method of claim 1 wherein the wavelengths of the multiple patterns are the same.

6. The method of claim 1 wherein the wavelengths of the multiple patterns are different.

7. The method of claim 1 wherein said multiple patterns comprise first, second and third different patterns.

8. The method of claim 1 wherein said multiple patterns are perpendicular.

9. The method of claim 1 wherein said directing step comprises passing radiation through a programmable mask, reprogramming said programmable mask, and then passing radiation through said reprogrammed programmable mask.

10. The method of claim 1 wherein said directing step directs different patterns toward said volume to define different parts of said structure.

11. The method of claim 1 further comprising developing said photosensitive materials.

12. The method of claim 1 further comprising directing multiple patterns to make multiple structures.

13. The method of claim 1 wherein said structure comprises a microfabrication.

14. The method of claim 1 wherein said directing step includes directing said irradiating energy toward said volume through multiple programmable masks.

15. The method of claim 1 wherein said method further includes taking advantage of symmetries of said structure to minimize the number of exposures.

16. A system for creating structures comprising:
an illuminating arrangement that directs multiple two-dimensional patterns of irradiating energy toward a volume of photosensitive material so that said multiple patterns intersect; and
a processing arrangement that subjects said irradiated photosensitive materials to a further process that creates a persistent 3D structure based on intersections between said multiple irradiating patterns.

17. The system of claim 16 wherein said illuminating arrangement directs said irradiating energy toward said volume through an alternative programmable mask.

18. The system of claim 16 wherein said illuminating arrangement projects multiple intersections of said two-dimensional patterns toward said photosensitive material.

19. The system of claim 16 wherein said photosensitive material comprises a photoresist that responds to the intersection between said multiple patterns.

20. The system of claim 16 wherein the wavelengths of the multiple patterns are the same.

21. The system of claim 16 wherein the wavelengths of the multiple patterns are different.

22. The system of claim 16 wherein said multiple patterns comprise first, second and third different patterns.

23. The system of claim 16 wherein said multiple patterns are perpendicular.

24. The system of claim 16 wherein the illuminating arrangement passes radiation through a programmable mask, reprograms said programmable mask, and then passes radiation through said reprogrammed programmable mask.

25. The system of claim 16 wherein said illuminating arrangement directs different patterns toward said volume to define different parts of said structure.

26. The system of claim 16 further comprising means for developing said photosensitive materials.

27. The system of claim 16 wherein said illuminating arrangement directs multiple patterns to make multiple structures.

28. The system of claim 16 wherein said structure comprises a microfabrication.

29. The system of claim 16 wherein said illuminating arrangement directs said irradiating energy toward said volume through multiple programmable masks.

30. The system of claim 16 wherein said system takes advantage of symmetries of said structure to minimize the number of exposures.
